(19) United States
(12) Patent Application Publication
(10) Pub. No.: US 2016/0093711 A1
(43) Pub. Date: Mar. 31, 2016

(54) Tantalum carbide metal gate stack for mid-gap work function applications

(71) Applicants: Intermolecular Inc., San Jose, CA (US); GLOBALFOUNDRIES, Inc.

(72) Inventors: Zhendong Hong, San Jose, CA (US); Paul Besser, Sunnyvale, CA (US); Kisik Choi, Watervliet, NY (US); Amol Joshi, Sunnyvale, CA (US); Olov Karlsson, San Jose, CA (US); Susie Tzeng, Fremont, CA (US)

(21) Appl. No.: 14/315,079

(22) Filed: Jun. 25, 2014

(51) Int. Cl. H01L 29/49; H01L 21/285; H01L 29/423; H01L 21/28

(52) U.S. Cl. CPC H01L 29/4966; H01L 21/28088; H01L 21/28556; H01L 29/42372

(57) ABSTRACT

Devices with lightly-doped semiconductor channels (e.g., FinFETs) need mid-gap (˜4.6-4.7 eV) work-function layers, preferably with low resistivity and a wide process window, in the gate stack. Tantalum carbide (TaC) has a mid-gap work function that is insensitive to thickness. TaC can be deposited with good adhesion on high-k materials or on optional metal-nitride cap layers. TaC can also serve as the fill metal, or it can be used with other fills such as tungsten (W) or aluminum (Al). The TaC may be sputtered from a TaC target, deposited by ALD or CVD using TaCl₄ and TMA, or produced by methane treatment of deposited Ta. Al may be added to tune the threshold voltage.

### BACKGROUND

Related fields include FinFETs and other mid-gap (lightly-doped) semiconductor devices, particularly work-function and fill metals for compatible metal gates.

Gate structure is often a critical element in semiconductor devices. The design, materials, size, and process sequence details of the gate structure determine attributes such as power consumption, speed, and reliability. As the size of semiconductor devices has been reduced, gate dielectric materials have changed from silicon dioxide to high-k dielectric materials (materials with higher dielectric constant k than SiO2, e.g., oxides of metals such as hafnium, zirconium, tantalum, titanium, lanthanum, and the like. Additionally, the conductive materials used as gate electrodes have been selected for work functions to match the underlying semiconductor (e.g., n-type or p-type silicon).

Low-power operation of electronic devices is increasingly important as device size decreases, particularly for radio frequency (RF) analog circuit design and system-on-chip (SoC) applications. Many RF/analog transistors operate in the saturation region for a higher transconductance. Low-power operation is also desirable in many types of portable electronics to extend the time between battery charges.

A FinFET is a particular type of nonplanar FET with a body in the form of a narrow, elongated semiconductor “fin” connecting the source to the drain. Usually FinFETs have at least two gates. Pairs or other subsets of FinFET gates may be connected to each other by a conductive channel that surrounds the fin on at least two (most often three) sides. In some FinFETs, the gates are electrically independent. FinFETs can operate at lower power than most planar FET devices because the fully depleted (lightly doped) thin body of the fin reduces or reverses short-channel effect with improved drain-induced barrier lowering. In addition, the lightly-doped channel of a FinFET is less affected by random dopant fluctuation than the more heavily-doped channel of a typical planar FET.

As Metal-Oxide-Semiconductor Field Effect Transistor (MOSFET) devices are shrinking in dimensions and moving towards 3-dimensional (3D) structures, such as FinFETs, it is increasingly difficult to use ion implantation (doping) to tune the device threshold voltage (Vₜₕ). An alternative method to tune the Vₜₕ is to use metals with varying work functions as the gate material in a high-k metal gate (HKMG) structure. FinFETs and other devices based on lightly-doped semiconductors (“mid-gap” devices) require different work-function materials for metal gates than devices based on heavily n- or p-doped semiconductors. NMOS devices require work functions near 4 eV and PMOS near 5 eV, but mid-gap devices may require work functions between 4.6 and 4.7 eV, depending on the doping. In addition, all the usual desirable qualities for a metal gate (good thermal stability with the underlying dielectric, low diffusivity to oxygen and other dopants, high carrier concentration to minimize gate depletion effects, low resistivity) apply to gates for mid-gap devices. A wide process window (tolerance for process conditions, both in its own fabrication and in the fabrication of other components on the same substrate) is also preferred.

Typically, after the metal gate is formed, a high-conductivity “fill” metal is deposited on top of it to electrically connect the gate with an overlying interconnect. For gate lengths less than 20 nm, the total thickness of metal gate and fill metal will need to be less than 5 nm. The ability to use the same metal as both gate and fill would be advantageous, both for meeting the new dimensional requirements and for simplifying production of existing devices. Such a metal would require both low resistivity and a work function that matches the underlying semiconductor.

Thus, a need exists for a process-tolerant work-function metal for mid-gap metal gates.

Preferably, the work-function metal would have sufficiently low resistivity to also function as a fill metal. However, compatibility with existing fill metals (e.g., tungsten and aluminum), is also useful.

### SUMMARY

The following summary presents some concepts in a simplified form as an introduction to the detailed description that follows. It does not necessarily identify key or critical elements and is not intended to reflect a scope of invention.

Tantalum carbide (TaC) in 5-10 nm thicknesses is used as a work-function metal in mid-gap devices with lightly-doped channels, including FinFETs. The TaC may be polycrystalline, or in particular polycrystalline-cubic. Aluminum (Al) may be added to the TaC, which in sufficient quantity may lower the work function. In some embodiments, TaC is also used as a fill layer in thicknesses of 30-50 nm, but alternatively a different conductive material may be used in the fill layer.

The TaC may be deposited by physical vapor deposition (PVD) at 20-30 C, sputtering from a TaC target at power densities of 1.5-4 W/cm². Alternatively, it may be deposited by deposits Ta metal and exposes it to methane (CH₄) to form TaC. Another alternative process may include atomic layer deposition (ALD) from precursors such as tantalum chloride (TaCl₄) and trimethylaluminum (TMA).

The metal gates may have the TaC in contact with a high-k dielectric layer, or an intervening thin (<˜5 nm) cap layer, such as a titanium nitride (TiN) layer, may be included between the high-k dielectric layer and the TaC. According to experimental data, the resistivity is low (less than ˜200 μΩ-cm, e.g., ˜160 μΩ-cm) and the effective work function (4.6-4.7 eV is mid-gap and may be lowered to ˜4.4 eV with added Al) is insensitive to film thickness, to the presence of a n intervening cap layer, to deposition and removal of a temporary cap layer, or to anneal temperatures up to 500 C. Leakage current and hysteresis were also thickness-insensitive.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A-1D are conceptual diagrams of gate stacks in different contexts.

FIG. 2 is a flowchart of some of the main processes for fabricating a gate stack.

FIG. 3 is a block diagram of a PVD apparatus for forming some non-conformal layers.

FIG. 4 is a block diagram of an ALD/CVD apparatus for forming some conformal layers.

FIGS. 5A-5C are graphs of experimental data on TaC layers.

FIG. 6A and 6B are conceptual diagrams of FinFET gate stacks with TaC as the work-function layer.

FIGS. 7A-7C are flowcharts of alternate methods for forming a TaC work-function layer.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

Unless the text or context clearly dictates otherwise: (1) By default, singular articles “a,” “an,” and “the” (or the absence of an article) may encompass plural variations; for example, “a layer” may mean “one or more layers.” (2) “Or” in a list of multiple items means that any, all, or any combination of less than all the items in the list may be used in the invention. (3) Where a range of values is provided, each intervening value is encompassed within the invention. (4) “About” or “approximately” contemplates up to 10% variation. “Substantially” contemplates up to 5% variation. “On” indicates direct contact; “above” and “over” allow for intervening elements. “On” and “over” include conformal layers covering feature walls oriented in any direction.

“Substrate,” as used herein, may mean any workpiece on which formation or treatment of material layers is desired. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter. “High-k material”, “high-k layer”, and “high-k dielectric” are used interchangeably herein to refer to a material and/or layer with a dielectric constant (“k”) greater than 7. “Conformal” herein shall mean at least 80% conformal. “Lightly doped” as used herein shall mean body doping N_{b} is less than 10¹⁷ cm⁻³.

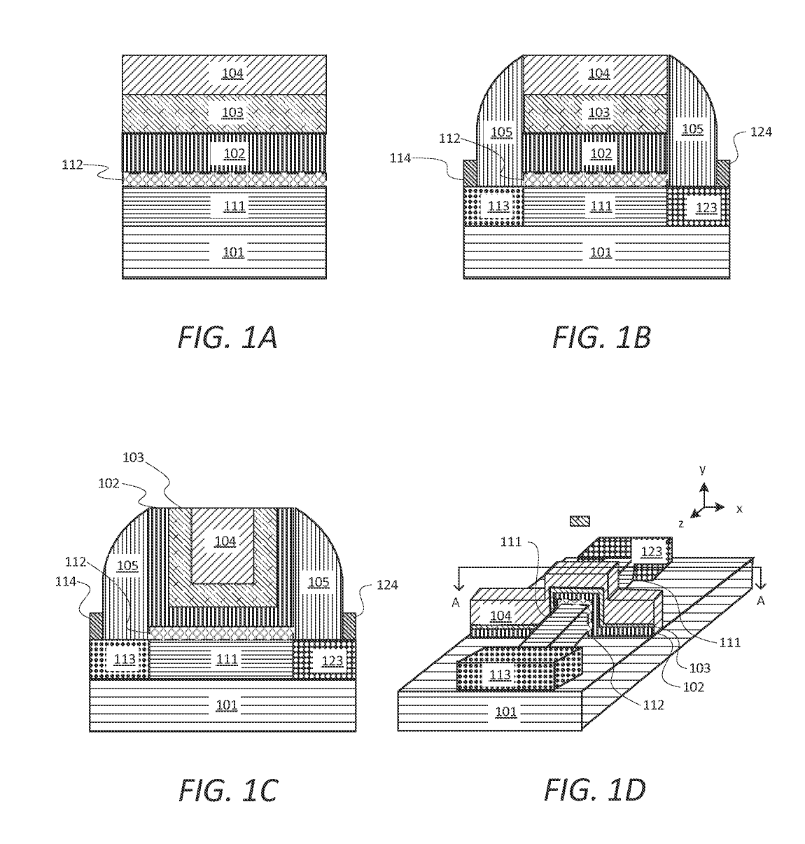

FIGS. 1A-1D are conceptual diagrams of gate stacks in different contexts. FIG. 1A is a simple block diagram of typical stack layers. Substrate 101 may have other layers and/or structures underneath those specifically illustrated. Body 111, formed over substrate 101, is usually a semiconductor, or may be a stack with at least one semiconducting layer. Depending on the design, body 111 (also called the “channel”) may or may not be the same material as, or contiguous with, substrate 101. High-k gate dielectric layer 102 (hereinafter “high-k layer 102”) is formed over body 111. In some embodiments, high-k layer 102 may be in direct contact with body 111, but in some embodiments an interface layer 112 may be interposed to prevent diffusion, reaction, or other unwanted interface phenomena between body 111 and high-k layer 102. Work-function layer 103, selected to produce a desired threshold voltage, is formed over high-k layer 102. Fill layer 104, selected for high conductivity, fills the space between work-function layer 103 and an interconnect or wiring (not shown) to connect the gate to one or more other components.

Non-limiting examples of materials for the gate stack layers include the following.

Substrate 101 may include, for example, silicon (Si), germanium (Ge), sapphire, zinc oxide, SiC, AlN, GaN, Spinel, coated silicon, silicon on oxide (SOI), silicon carbide on oxide, glass, gallium nitride, indium nitride and aluminum nitride, and combinations or alloys thereof. Body 111 may include Si, Ge, III-V materials, or alloys thereof with work functions between 4.3 and 4.7 eV. Interface layer 112 may include silicon dioxide (SiO₂) or titanium dioxide (TiO₂). High-k layer 102 may include stoichiometric or non-stoichiometric hafnium oxide (HfOₓ), zirconium oxide (ZrOₓ), tantalum oxide (TaOₓ), titanium oxide (TiOₓ), aluminum oxide (AlOₓ), yttrium oxide (YOₓ), lanthanum oxide (LaOₓ), analogous nitrides or oxynitrides, compounds or alloys thereof, or any other high-k dielectric with suitable barrier height, thermodynamic stability, interface quality, gate compatibility, process compatibility, and fixed oxide charge. Work-function layer 103 is chosen for a bandgap similar to body 111, which in turn depends on the base material and dopants in body 111. The main work-function material discussed herein is TaC. Fill metals discussed herein may include TaC and W.

FIG. 1B shows the gate stack of FIG. 1A in a “gate-first” planar FET. The gate stack layers (interface layer 112, high-k layer 102, work-function layer 103, and fill layer 104) are simple plane layers because the gate stack was formed and patterned first; then the surrounding structures such as source 113, drain 123, source electrode 114, drain electrode 124, and spacers 105 were formed around the gate stack. Some materials used in high-k layer 102, however, cannot tolerate the process conditions required to form some of the surrounding structures.

FIG. 1C shows the gate stack of FIG. 1A in a “gate-last” or “replacement-gate” planar

FET. This approach initially forms the surrounding structures such as source 113, drain 123, source electrode 114, drain electrode 124, and spacers 105 around a sacrificial “dummy” gate (dummy gate materials include, for example, polycrystalline Si). Then the dummy gate is removed, and the gate stack layers are formed in the resulting opening. Depending on the formation method, the gate stack layers may or may not substantially line the sidewalls of the opening (i.e., they may or may not be conformal).

FIG. 1D shows an example of a 3D FinFET. In some embodiments, such as SOI (silicon-on-insulator), substrate 101 may include a top layer of buried oxide (BOX). In other embodiments, the top layer of substrate 101 may be the same material as body 111. Body 111 is an elongated “fin” raised in relief above substrate 101. The height of fin 111 (y-dimension on the illustrated axes) may be between 2 and 6 times its width (x-direction). Source 113 and drain 123 are also raised structures, positioned at the ends of body 111. Interface layer 112, high-k layer 102, and work-function layer 103 are conformal, “wrapping around” three sides of body 111. Because the sides of body 111 are exposed before forming interface layer 112, that layer may still be formed by oxidizing a thin outer portion of body 111, if desired. Fill layer 104 “buries” the gate stack and may extend to other FinFET bodies formed parallel to body 111.

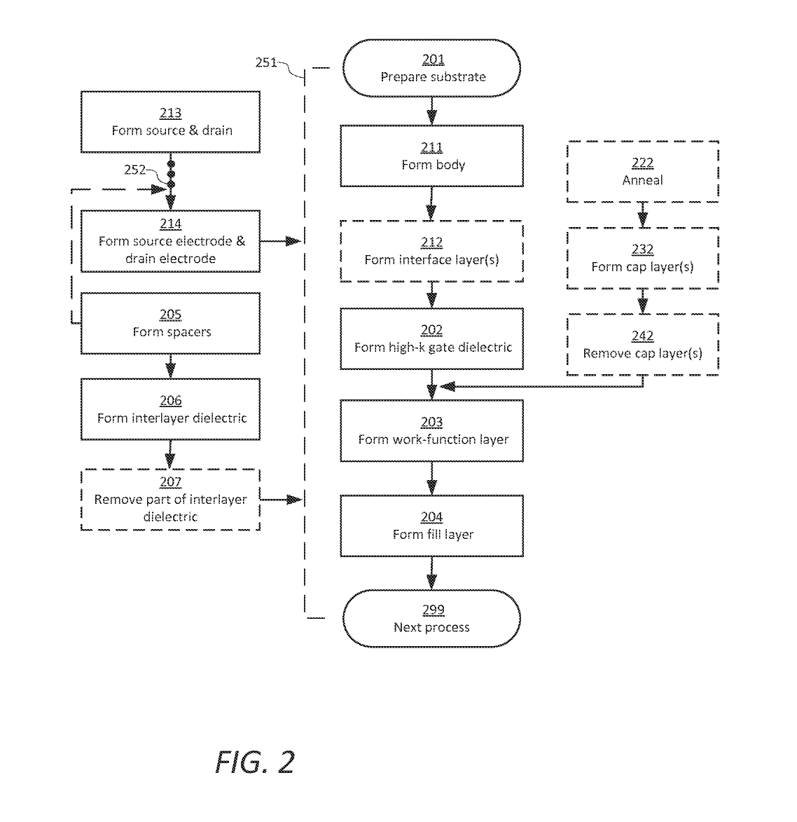

FIG. 2 is a flowchart of some of the main processes for fabricating a gate stack. The step numbering, where appropriate, may be non-consecutive so that the formation step numbers are analogous to the formed features in FIGS. 1A-1D. Reference numbers beginning with “1” refer back to FIGS. 1A-1D. Substrate 101 is prepared 201. Body 111 is formed 211 by any method appropriate to the device, such as etching the fin of a FinFET. If needed to separate the high-k gate dielectric from the work-function layer, one or more interface layers 112 may be optionally formed 212. The high-k gate dielectric 102 is then formed 202. The work-function layer 103 is formed 203. The fill layer 104 is formed 204; then the next process may commence 299.

In some embodiments, intervening steps after high-k layer formation 202 may include annealing 222, optional formation 232 of one or more intervening cap layers, and optional removal 242 of some or all of the intervening cap layers. The cap layers may temporarily protect the high-k layer and be removed just before the work-function layer is deposited, or the cap layers may be permanently incorporated into the gate stack (e.g., adhesion layers that prevent agglomeration of the work-function layer during later anneals, or barrier layers that prevent diffusion between the high-k and work-function layers). For example, after annealing, a TiN cap may be formed on the high-k layer, an additional sacrificial cap of Si may be formed over the TiN cap, with the Si cap being removed before work-function layer formation.

The gate stack layers may be deposited by a vacuum-based or “dry” process such as PVD, ALD, PE-ALD, AVD, UV-ALD, CVD, PECVD, or evaporation. Alternatively, it may be deposited by a solution-based or “wet” process such as printing or spraying of inks, screen printing, inkjet printing, slot die coating, gravure printing, wet chemical depositions, or from sol-gel methods, such as the coating, drying, and firing of polysilazanes. If coverage of structure sidewalls is required, a conformal process such as atomic layer deposition (ALD), chemical vapor deposition (CVD), or a low-viscosity wet deposition may be selected.

Other structures of the transistor are also formed, but the timing of the formation of these other structures in relation to the gate stack formation can vary by device and method. This is symbolized by the arrows from these other processes pointing to the dotted bracket 251 bracketing the main gate-stack process. The source 113 and drain 123 may, in different devices, be formed before, during, or after formation of the body and gate stack. Source electrode 114 and drain electrode 124 are generally formed 214 after the source and drain formation 213, but there may be intervening steps represented by vertical ellipsis 252. The intervening steps may include some of the gate stack formation 212, 202, 203, 204, and/or may include forming 205 the spacers 105. After spacer formation 205, an interlayer dielectric may be formed 206 and then partially removed 207.

For example, in the planar devices of FIGS. 1B and 1C, the body 111 is defined by the space between a source and a drain, so source and drain formation 213 is be co-incident with body formation 211.

In the gate-first device of FIG. 1B, the source and drain formation 213, source electrode and drain electrode formation 214, spacer formation 205, interlayer dielectric formation 206, and partial interlayer dielectric removal 207 are done after formation of at least part of the gate stack, and the interlayer dielectric is partially removed 207 to expose the top of the gate stack. Because the gate stack layers in this device are initially deposited on a flat surface, “step coverage” or conformality is not an issue and all the layers may be deposited by a non-conformal method such as PVD. Alternatively, they may be formed by methods capable of conformality such as CVD or ALD if those methods confer other advantages (e.g., surface smoothness, composition flexibility, precise control of thickness).

By contrast, in the gate-last device of FIG. 1C, the other structure formations 213, 214, 205, 206, and 207 precede the gate-stack formations 212, 202, 203, or 204. The other structures are initially formed around a temporary “dummy” gate that is removed after partial removal 207 of the interlayer dielectric; then the gate stack is formed 212, 202, 203, and 204 in the opening left by the dummy gate's removal. In the particular example of FIG. 1C, interface layer 112 was formed by a non-conformal method 212; it may be, for example, an oxide of the underlying body material created by thermal oxidation or surface reaction in an oxidant soak. Alternatively, a conformal interface layer could be formed 212 by ALD or CVD. Fill layer 104 is also non-conformal; for example, it may have been formed by physical vapor deposition (PVD). FIG. 1C's high-k layer 102 and work-function layer 103 are conformal, lining the sidewalls as well as the bottom of the opening between spacers 105; their formation processes 202 and 203 may be ALD or CVD.

In the FinFET of FIG. 1D, body 111 (the fin) can be formed 211 by, for example, reactive ion etching (RIE) or anisotropic wet etching of a blanket layer, or it may be formed by a selective growth process. Optionally, the corners, or the extents of the corners intended to be covered by the gate, may be rounded or beveled. As illustrated, the gate stack layers 112, 102, and 103 cover the sidewalls of body 111, resulting from conformal processes for their formation 212, 202, and 203. Fill 104 need not be conformal, so fill formation 204 need not be a conformal process.

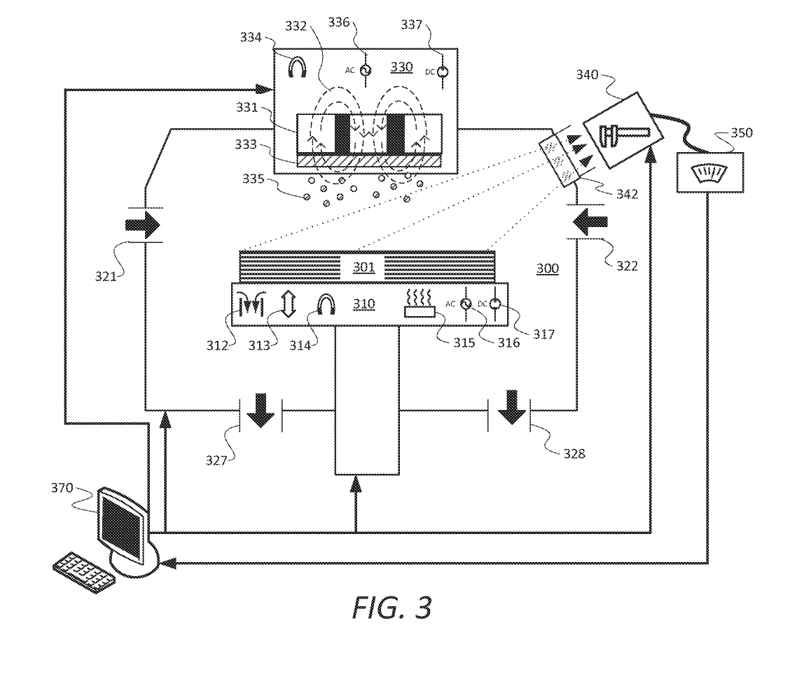

FIG. 3 is a block diagram of a PVD apparatus for forming some non-conformal layers.

Chamber 300 includes a substrate holder 310 for holding a substrate 301. Substrate holder 310 may include a vacuum chuck 312, translation or rotational motion actuators 313, a magnetic field generator 314, a temperature controller 315, and circuits for applying an AC voltage bias 316 or DC voltage bias 317 to substrate 301. Some chambers include masks (not shown) for exposing only part of substrate 301 to the PVD process. The masks may be movable independent of the substrate. Chamber 300 includes inlets 321, 322 and exhausts 327, 328 for process gases. Process gases for PVD may include inert gases such as nitrogen or argon, and may also include reactive gases such as hydrogen or oxygen.

Chamber 300 includes least one sputter gun 330 for sputtering elementary particles 335 (such as atoms or molecules) from a sputter target 333 by means of plasma excitation from the electromagnetic field generated by magnetron 331. Sputter gun 330 may include adjustments for magnetic field 334, AC electric field 336, or DC electric field 337. Some sputter guns 330 are equipped with mechanical shutters (not shown) to quickly start or stop the exposure of substrate 301 to elementary particles 335. Some PVD chambers have multiple sputter guns.

Some chambers 300 support measuring equipment 340 that can measure characteristics of the substrate 301 being processed through measurement ports 342. Results for measuring equipment 340 may be monitored by monitoring equipment 350 throughout the process, and the data sent to a controller 370, such as a computer. Controller 370 may also control functions of substrate holder 310, chamber 300 and its gas inlets and outlets 321, 322, 327, and 328, sputter gun 330, and measurement equipment 340.

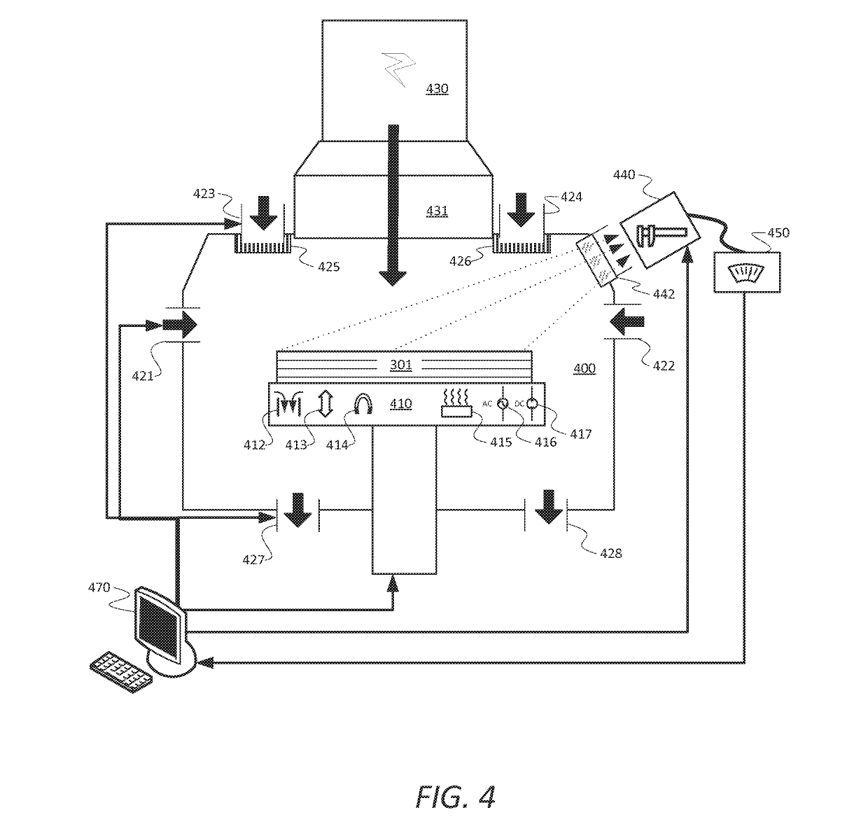

FIG. 4 is a block diagram of an ALD/CVD apparatus for forming some conformal layers.

Inside chamber 400, substrate 401 is held by a substrate holder 410. Substrate holder 410 may be configured with vacuum 412 (for example, a vacuum chuck to grip the substrate); motion 413 in any direction, which may include tilt and rotation; a magnetic field source 414; heater or temperature control 415; or sources of AC 416 or DC 417 bias voltage, or static electrical charge for an electrostatic chuck to hold the substrate (not shown). Chamber 400 also has gas inlets 421, 422, 423, 424 for precursors, buffer gases, and purge gases. Some of the inlets may feed through diffusers 425, 426. In plasma-enabled chambers, a remote plasma chamber 430 may generate reactive species that enter chamber 400 through input adapter 431, or a direct plasma may be generated at or near the surface of substrate 401. Measurement system 440 may monitor substrate 401 through measurement ports 442. The measurements from measurement system 440 may be collected by a monitoring system 450 and sent for analysis or storage to a data collection device such as computer 470. Substrate holder 410, gas inlets 421-324, diffusers 425-26, remote plasma chamber 430, plasma input adapter 431, exhausts 427-28, measurement system 440, and monitoring system 450 may jointly or individually be controlled by controllers such as computer 470.

Substrate 401 may be held on substrate holder 410 electrostatically, by vacuum, or by any other suitable means. Precursors for making the layers, as well as other process gases or species such as buffers or catalysts, may enter through plasma input adapter 431, undiffused gas inlets 421 and 422, or gas inlets 423 and 424 with diffusers 425 and 426. Precursors may be introduced into chamber 400 in “pulses,” short periods of inflow followed by a delay to allow a portion of the precursor to adsorb on the surface of substrate 401, or the inflow may be continuous. To promote or regulate the adsorption of the deposited material from the precursors, substrate 401 may be heated or cooled 415, AC- or DC-biased 416 or 417, or subjected to a magnetic field 414 by substrate holder 410.

Exhausts 427 and 428 may equalize the pressure for continuously flowing precursors. Measurement equipment 440 may dynamically measure characteristics of the surface of substrate 401 so that monitoring equipment 450 may track the progress of precursor deposition. After each pulse or period of precursor inflow, chamber 400 may be purged by drawing any gaseous contents out through exhausts 427 and 428. In some embodiments, a purge gas may be routed through chamber 400. Purge gases are often inert gases such as nitrogen and argon, but other types of purge gases are sometimes used. The temperature, electric field, or magnetic field of substrate 401 may also be adjusted during the purge.

For devices needing a work-function layer with work function ˜4.6-4.7eV (e.g., mid-gap Si), TaC appears to have several advantages based on experimental results. Its resistivity is low (˜200 μΩ-cm for a 5 nm layer or ˜160 μΩ-cm in bulk), low enough to also function as a fill metal. Its work function can be reduced by ˜0.01-0.3 eV, if desired, by adding Al. The TaC or TaAlC adheres well to metal-nitride cap layers such as TiN, and it also adheres well directly to high-k materials such as hafnium oxide. If TaC is used only as a work-function layer, other fill metals such as W adhere well to the TaC. Its work function and resistivity are insensitive to the presence of capping layers and also to wet processes, such as exposure to dilute sulfuric acid/hydrogen peroxide (DSP+) solution or chemical-mechanical polishing (CMP), that remove temporary capping layers. In addition, a number of characteristics are highly insensitive to film thickness, affording a wide process window.

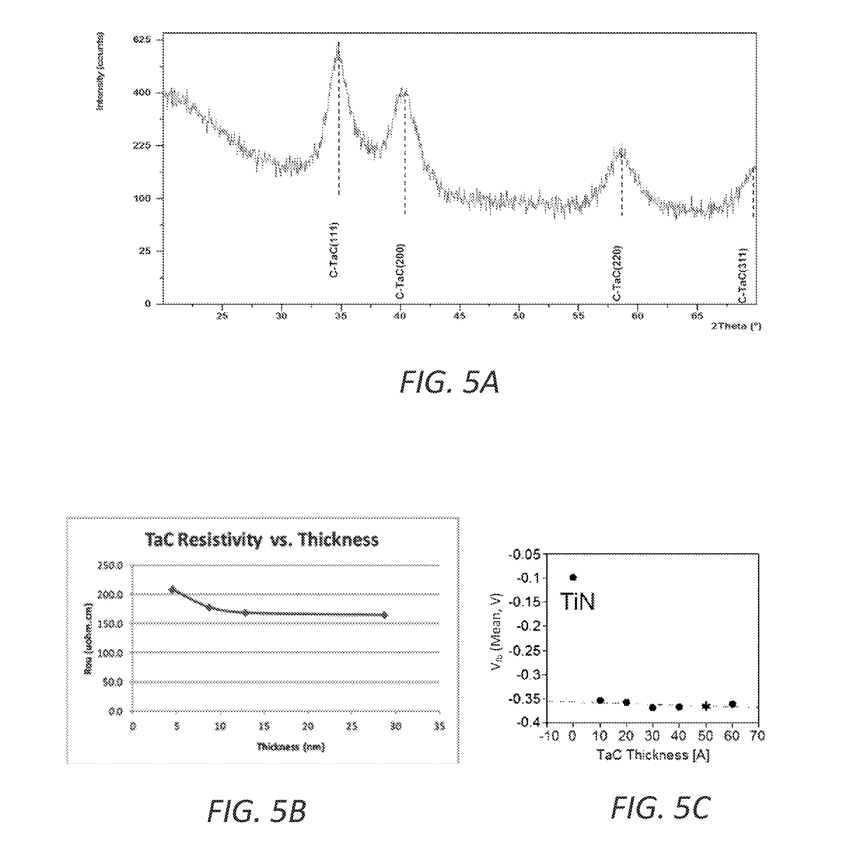

FIGS. 5A-5C are graphs of experimental data on TaC layers. These layers had a density, measured by X-ray reflectometry, of about 14.5 g/cm³. FIG. 5A shows an X-ray diffraction (XRD) measurement of the TaC with peaks characteristic of polycrystalline-cubic morphology. The morphology did not change significantly after a 500 C, 30 min subsequent anneal. In FIG. 5B, measurements of resistivity vs. thickness are almost flat near ˜160 μΩ-cm above about 12 nm thickness, and still low (<210 μΩ-cm) at 5 nm. In FIG. 5C, the flatband voltage V_{fb} of TaC is lower than that of a TiN reference and is also insensitive to thickness. In MIS structures without fixed charge or interface states, the metal work function WFₘ=V_{fb}−WFₛ, where WFₛ is the semiconductor work function. The experiments used p-type Si, doped to bring its work function to ˜5 eV. Thus the FIG. 5C graph indicates that the metal work function WFₘ for TaC=5-0.35˜=4.65 eV. Other characteristics that were insensitive to thickness over a range of 10-60 nm include capacitance effective thickness (˜0.04 nm delta-in-median), leakage current (˜1 A/cm² delta-in-median), and hysteresis (˜1.5 mV delta-in-median).

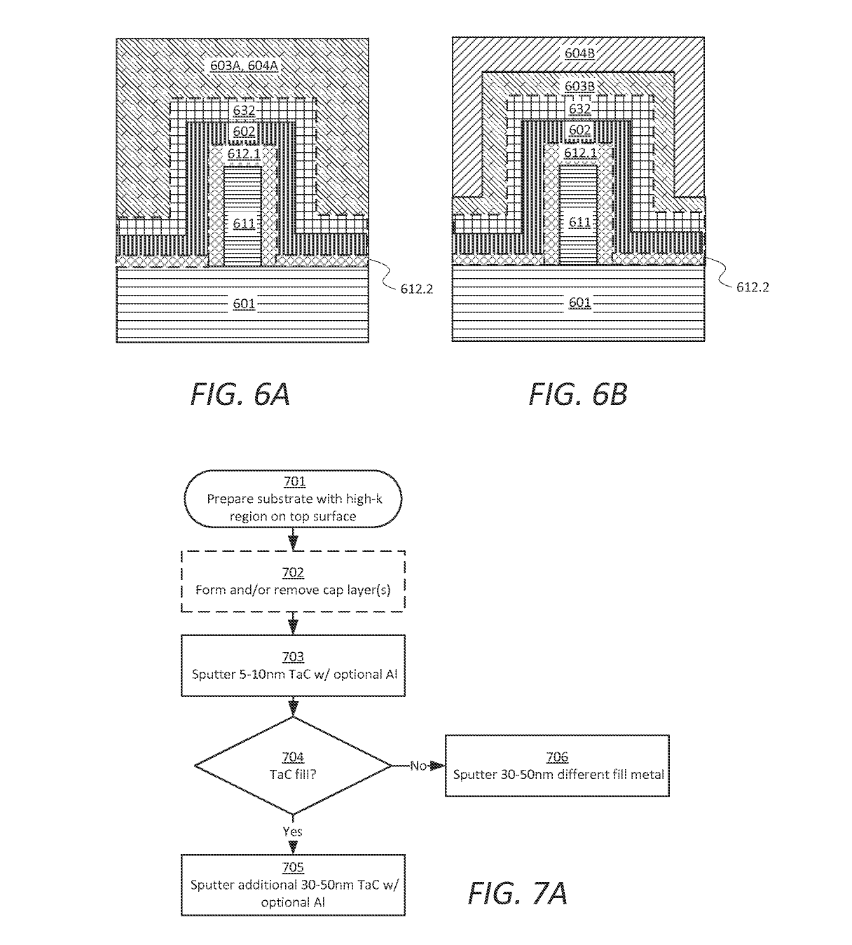

FIG. 6A and 6B are conceptual diagrams of FinFET gate stacks with TaC as the work-function layer. They may be considered as sectional views through section A-A of FIG. 1D. In FIG. 6A, the fill layer is also TaC. Body 611 (e.g., lightly-doped Si) is formed on (or from) substrate 601 and covered with optional interface layer 612.1 (e.g., SiO2). In some embodiments, the interface layer may also have lateral extensions 612.2 over substrate 601, depending on the substrate material (e.g., Si or BOX) and on the method of forming the layer (e.g., thermally or chemically altering the existing material, or depositing new material). High-k layer 602 is formed over interface layer 612.1 (or, in embodiments without interface layer 612, over body 611). In some embodiments, a permanent cap layer 632 (e.g., TiN or amorphous Si) may optionally remain over high-k layer 602. A 35-60 nm layer of TaC, with or without added Al, serves as a combined work-function layer 603A and fill layer 604A.

In FIG. 6B, substrate 601, body 611, optional interface layer portions 612.1 and 612.2, high-k layer 602, and optional permanent cap layer 632 are analogous to their counterparts in FIG. 6A. However, only the work-function layer 603B is TaC (with or without added Al). Fill layer 604B is a different material (e.g., it may be W). There are a number of reasons a different fill metal might be expedient. By way of non-limiting example, if the TaC work-function layer is deposited by ALD, it may take an undesirably long time to build up a layer thick enough for a fill metal (e.g., >30 nm).

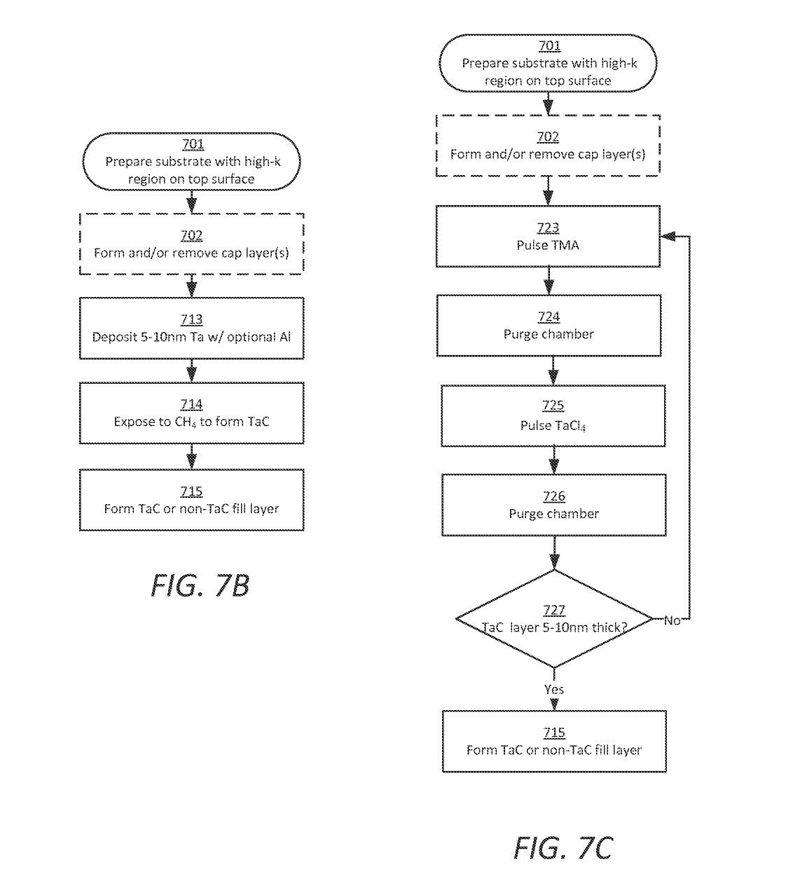

FIGS. 7A-7C are flowcharts of alternate methods for forming a TaC work-function layer. In FIG. 7A, the method uses PVD. A substrate (which can have any number of existing layers or structures) is prepared 701. In some embodiments, cap layers may be formed and optionally removed (as described for steps 232 and 242 in FIG. 2). A 5-10 nm thickness of TaC is sputtered 703 from a composite TaC target to form the work-function layer. For example, the target may be sputtered at a DC power density of about 1.5-4 W/cm², at a chamber pressure of about 3 millitorr, at a temperature between 20 and 30 C, for a time between 10 and 60 minutes. During the sputtering, Ar gas may flow into the chamber at a rate between about 10 and about 30 sccm.

Optionally, some aluminum may be added to the TaC. This may be done by using a composite Al: TaC target, co-sputtering Al from a second target, or any other suitable doping method such as ion implantation. If a TaC fill layer is desired 704, an additional 30-50 nm TaC is sputtered 705, with or without added Al. If different fill metal, such as W, is desired 704, 30-50 nm of the different fill metal 706 can be sputtered 706. In some embodiments, a PVD chamber with two sputter guns may sputter the different fill metal in-situ on top of the TaC without breaking vacuum or transferring the substrate to another chamber. Alternatively, the different fill metal may be deposited by some other method.

In FIG. 7B, the method uses carbon-incorporation of deposited Ta metal. After the substrate preparation 701 and optional capping/cap removal 702, 5-10 nm Ta is formed 713. Optionally, some Al may be added to the Ta, either by co-deposition or by doping after the layer is formed. PVD or any other suitable deposition method may be used. Either during or after the Ta formation 713, the substrate is exposed 714 to a carbon-incorporating agent such as CH₄. The carbon-incorporating agent reacts with the Ta to form the TaC work-function layer. If needed for the reaction, the substrate may be heated. Alternatively, carbon may be implanted in the Ta layer. Next, the fill layer is formed 715. This may include forming an additional 30-50 nm of TaC, by the same method or a different one. Alternatively, it may include forming 30-50 nm of a different fill metal, such as W, by any suitable method.

In FIG. 7C, the method uses ALD. After the substrate preparation 701 and optional capping/cap removal 702, the substrate is exposed to alternating pulses of the precursors trimethyl aluminum (“TMA,” (CH₃)₃Al) 723 and tantalum chloride (TaCl₄) 725 with a first chamber purge 724 after each TMA pulse and a second chamber purge 726 after each TaCl₄ pulse. The pulses may be in the reverse order, with TaCl₄ first and TMA second. However, if oxides need to be removed from the underlying layer, TMA is known to reduce oxides of materials with oxygen affinity less than that of Al, and may therefore be advantageous to use as the first pulse. In forming the TaC, the TMA provides C (and, typically, some Al), and the TaCl₄ provides Ta. Each cycle of pulses and purges 723-726 deposits a monolayer (or a sub-monolayer, if not all the available reaction sites on the substrate are used) of TaC. Inert purge gases such as Ar may be injected during the purges to help carry away unreacted precursors, detached precursor ligands, or other by-products. The cycles are repeated 727 to produce the 5-10 nm TaC work-function layer. Then the 30-50 nm TaC or non-TaC fill layer is formed 715 by any suitable method. A TaC fill layer may also include aluminum.

An alternate CVD method is very similar to the ALD method of FIG. 7C, except that the layer need not be created one monolayer or sub-monolayer at a time. Both the Ta and C precursors may simultaneously be in the chamber, combining pulses 723 and 725 and omitting purges 724 and 726, so that the deposition process becomes continuous.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A metal gate stack, comprising:
a substrate;
a lightly-doped semiconductor device body formed over the substrate;
a high-k layer formed over the lightly-doped semiconductor device body; and
a carbide layer formed over the high-k layer;
wherein the semiconductor device body comprises silicon;
wherein the carbide layer comprises tantalum carbide; and
wherein an effective work function of the carbide layer in the gate stack is between about 4.4 and about 4.7 eV.

2. The metal gate stack of claim 1, wherein the carbide layer is 5-10 nm thick.

3. The metal gate stack of claim 1, wherein the carbide layer is 35-60 nm thick.

4. The metal gate stack of claim 1, further comprising a conductive layer formed over the carbide layer.

5. The metal gate stack of claim 4, wherein the conductive layer is 30-50 nm thick.

6. The metal gate stack of claim 4, wherein the conductive layer comprises tungsten or aluminum.

7. The metal gate stack of claim 1, wherein the carbide layer further comprises aluminum.

8. The metal gate stack of claim 1, wherein the carbide layer has a resistivity less than 200 micro-ohm-centimeters.

9. The metal gate stack of claim 1, further comprising an interface layer between the semiconductor device body and the high-k layer.

10. The metal gate stack of claim 1, further comprising an intervening layer between the high-k layer and the carbide layer.

11. A method, comprising:
forming a high-k layer over a lightly-doped semiconductor device body disposed on a substrate; and
forming a carbide layer over the high-k layer;
wherein the semiconductor device body comprises silicon;
wherein the carbide layer comprises tantalum carbide; and
wherein an effective work function of the carbide layer in the gate stack is between about 4.4 and about 4.7 eV.

12. The method of claim 11, wherein the carbide layer is formed by physical vapor deposition from a target comprising tantalum carbide.

13. The method of claim 12, wherein the carbide layer further comprises aluminum.

14. The method of claim 11, wherein the carbide layer is formed by incorporating carbon into a layer comprising tantalum.

15. The method of claim 14, wherein the carbon-incorporating comprises exposing the layer comprising tantalum to methane.

16. The method of claim 11, wherein the carbide layer is formed by atomic layer deposition or chemical vapor deposition.

17. The method of claim 11, wherein the atomic layer deposition or chemical vapor deposition uses tantalum chloride and trimethyl aluminum as precursors.

18. The method of claim 11, further comprising forming an intervening layer over the high-k layer before the carbide layer is formed.

19. The method of claim 18, further comprising removing the intervening layer before the carbide layer is formed.

20. The method of claim 11, further comprising forming a conductive layer over the carbide layer.
